(19) United States
(12) Patent Application Publication
(10) Pub. No.: US 2003/0205813 A1
(43) Pub. Date: Nov. 6, 2003

(54) METHOD OF FORMING A MULTI-LAYERED WIRING STRUCTURE INCORPORATION IN SEMICONDUCTOR INTERGRATED CIRCUIT DEVICE AND HAVING LARGE ELECTROMIGRATION RESISTANCE.

(75) Inventor: Yumi Saitoh, Tokyo (JP)

Correspondence Address: SUGHRUE MION ZINN MACPEAK & SEAS, PLLC, 2100 Pennsylvania Avenue, NW, Washington, DC, 20037-3213, US

(73) Assignee: NEC CORPORATION

(21) Appl. No.: 09/922,737

(22) Filed: Aug. 7, 2001

Related U.S. Application Data
(62) Division of application No. 09/212,266, filed on Dec. 16, 1998, now abandoned.

(30) Foreign Application Priority Data
Dec. 17, 1997 (JP) 9-347914

(51) Int. Cl. H01L 29/40; H01L 23/52; H01L 23/48

(52) U.S. Cl. 257/758

(57) ABSTRACT

A multi-layered wiring structure has a tungsten plug embedded in an inter-level insulating layer and an upper aluminum alloy line held in contact with the upper surface of the tungsten plug and a reservoir projecting beyond the tungsten plug, and electric current flows from the upper aluminum alloy line into the tungsten plug, wherein the gradient of current density toward reservoir is larger than the gradient of current density toward the upstream side so that the reservoir effectively supplements aluminum atoms to vacancy generated around the boundary between the upper aluminum alloy line and the tungsten plug, thereby enhancing the resistance against the electromigration.

### FIELD OF THE INVENTION

This invention relates to a semiconductor integrated circuit device and, more particularly, to a multi-layered wiring structure incorporated in the semiconductor integrated circuit device.

### DESCRIPTION OF THE RELATED ART

Various circuit components are incorporated in the semiconductor integrated circuit device, and are connected through the multi-layered wiring structure. An inter-level insulating layer spaces the upper conductive lines from the lower conductive lines, and conductive plugs such as tungsten plugs provide vertical interconnections between the lower conductive lines and the upper conductive lines.

The multi-layered wiring structure is fabricated as follows. First, the lower conductive lines are patterned on an insulating layer, and, thereafter, are covered with an inter-level insulating layer. The inter-level insulating layer is selectively etched away through a photo-lithographic process and an etching process, and contact holes are formed in the inter-level insulating layer. Contact portions of the lower conductive lines are exposed to the contact holes, and the contact holes are plugged with tungsten pieces. The tungsten pieces are held in contact with the contact portions of the lower conductive lines. Conductive material such as aluminum or aluminum alloy is deposited over the inter-level insulating layer, and the conductive material layer is patterned into the upper conductive lines.

When the multi-layered wiring structure has more than two levels. The upper conductive lines are covered with another inter-level insulating layer, and the above described steps are repeated for the third-level conductive lines. If the conductive lines are wide enough to enlarge the contact holes, the upper conductive lines may be directly held in contact with the lower conductive lines without the tungsten plugs.

The conductive lines have been narrowed, and the nesting tolerance between the conductive lines and the contact holes becomes small. In order to increase the nesting tolerance, the conductive lines are partially widened, and the contact holes are formed over the wide contact portions. The wide contact portion allows the contact hole to be slightly offset from the target area. However, the wide contact portions cause the conductive lines to be widely spaced, and the manufacturer hardly enhances the density of the conductive lines. The width of the conductive lines are equal to the gap between the conductive lines in an ultra large scale integration, and the manufacturer designs the contact holes as wide as possible in so far as the contact holes do not extend beyond the periphery of the conductive lines.

A borderless via structure is attractive for the ultra large scale integration. The manufacturer can form a contact hole approximately equal in width to an upper conductive line without a wide contact portion by using the borderless via structure. The difference between the borderless via structure and the conventional standard structure is clearly understood from FIGS. 1A and 1B.

FIG. 1 shows the conventional multi-layered wiring structure. A contact hole 1 is formed in an inter-level insulating layer 2, and is plugged with a tungsten piece 4. An upper aluminum alloy line 4 is patterned on the inter-level insulating layer 2, and has a wide contact portion 4a. The tungsten piece 3 is held in contact with the wide contact portion 4a as shown.

On the other hand, FIG. 2 shows the prior art multi-layered wiring structure categorized in the borderless via structure. A contact hole 5 is formed in an inter-level insulating layer 6, and is plugged with a tungsten piece 7. An upper aluminum alloy wiring 8 is patterned on the inter-level insulating layer 6, and has a constant width approximately equal to the width of the contact hole 5. The tungsten piece 7 is held in contact with one end portion of the upper aluminum alloy line 8 without offset, and is further held in contact with a lower aluminum alloy line 9 (see FIG. 3).

A problem is encountered in the prior art multi-layered wiring structures in that the upper aluminum alloy lines 4/8 raises the resistance due to electromigration phenomenon. The electromigration proceeds as follows. The flux of aluminum atom is discontinuous at the boundary between the upper aluminum alloy line 4/8 and the tungsten piece 3/7, and a vacancy takes place. The vacancy is grown to a void with time, and the void increases the resistance. Finally, the upper aluminum line is disconnected. When electric current flows as indicated by arrows AR1, the void is produced in the contact portion 10. The upper aluminum alloy line 8 is as wide as the tungsten piece 7, and the contact portion 10 is smaller in volume than the wide contact portion 4a. For this reason, the upper aluminum alloy line 8 is shorter in durability than the aluminum alloy line 4.

In order to improve the durability, a reservoir 11 is added to the upper aluminum alloy line 8 as shown in FIG. 4. The reservoir 11 supplements aluminum atoms to the boundary between the upper aluminum alloy line 8 and the tungsten plug 7, and the void 12 is grown in the reservoir 11 instead of the contact portion 10. When the void 12 reaches the boundary, the upper aluminum line 8 reaches the end of the life. Thus, the reservoir 11 prolongs the duration of the upper aluminum alloy line 8. The wide contact portion 4a is a kind of reservoir, and the reservoir is unintentionally added to the upper aluminum alloy line 4. The upper aluminum alloy line 8 extends beyond the tungsten piece 7, and the reservoir 11 is intentionally added to the upper aluminum alloy line 8.

The reservoir 11 is fairly effective against the void at the boundary between the tungsten piece 7 and the upper aluminum alloy line 8. However, the reservoir 11 can not supplement the aluminum atom to a void 13 generated on the upstream side of the boundary (see FIG. 5). Thus, the aluminum alloy line 8 still suffers from the electromigration.

### SUMMARY OF THE INVENTION

It is therefore an important object of the present invention to provide a multi-layered wiring structure, which is durable against the electromigration without sacrifice of the integration density.

The present inventor contemplated the problem due to the electromigration, and investigated the development of the void on the basis of the two principles. The first principle was that generation of vacancy was promoted under large current density. The second principle was that the vacancy was diffused along a gradient of vacancy density. Therefore, the vacancy was diffused along the largest gradient of current density.

The electric current flowed from the upper aluminum alloy line 4/8 through the boundary to the tungsten plug 3/7, and the electric current on the lower surface of the upper aluminum alloy line 4/8 was maximized at the corner MAX1. For this reason, the vacancy was maximized at the corner MAX1 closer to the upstream side of the current, and was diffused along the gradient of density. The wide contact portion 4a was located around the tungsten piece 3, and could supplement the aluminum atom in all the directions. There is no need to take the maximum gradient of current density into account. However, the prior art reservoir 11 was located on the opposite to the upstream side of current, and supplemented the aluminum atom in the opposite direction to the current. In this situation, the gradient of current density strongly affected the supplement of the aluminum atom. The prior art reservoir 11 was not located on the maximum gradient of current density. In the case shown in FIG. 5, the maximum gradient extended toward the upstream side, and the aluminum atom was supplemented from the upper aluminum alloy line 8. The present inventor concluded that the reservoir had to be located on the maximum gradient of current density. The present inventor found that the current density was controllable by regulating the ratio between the thickness of a conductive line and the length of a conductive piece in the direction of current. In the prior art multi-layered wiring structure shown in FIG. 5, the ratio of the thickness to the length was greater than 1.0, and the maximum gradient was directed along the upper aluminum alloy line 8.

To accomplish the object, the present invention proposes to make the gradient of current density from a reservoir to a conductive plug larger than the gradient of current density from a conductive line to the conductive plug.

In accordance with one aspect of the present invention, there is provided a multi-layered wiring structure incorporated in a semiconductor integrated circuit device comprising an inter-level insulating layer having at least one contact hole open to an upper surface thereof and a lower surface thereof, a conductive strip of a first conductive material formed on the inter-level insulating layer, extending over the contact hole, and providing a boundary region over the contact hole, a current path on an upstream side of the boundary region and a reservoir located on the opposite to the current path with respect to the boundary region and supplying metal atom to vacant generated in the conductive strip and a conductive plug formed of a second conductive material different from the first conductive material, filling the at least one contact hole and held in contact with the boundary region so that electric current flows from the current path through the boundary region into the conductive plug, the electric current density is maximized at a certain position in the boundary region, and a gradient of the electric current density from the certain position toward the reservoir is larger than a gradient of the electric current density from the certain position toward the upstream side of the current path.

### BRIEF DESCRIPTION OF THE DRAWINGS

The features and advantages of the multi-layered wiring structure will be more clearly understood from the following description taken in conjunction with the accompanying drawings in which:

FIG. 1 is a plane view showing the contact hole nested in the wide contact portion of the upper conductive wiring fabricated through the conventional wiring technology;

FIG. 2 is a plane view showing the contact hole nested in the narrow upper conductive line of the borderless via structure;

FIG. 3 is a cross sectional view showing the structure of the prior art multi-layered wiring structure;

FIG. 4 is a cross sectional view showing the structure of the prior art multi-layered wiring structure equipped with a reservoir;

FIG. 5 is a cross sectional view showing the void generated in the intermediate portion of the upper aluminum alloy line forming a part of the structure of the prior art multi-layered wiring structure;

FIG. 6 is a plane view showing the layout of a multi-layered wiring structure according to the present invention;

FIG. 7 is a cross sectional view showing the structure of the multi-layered wiring structure;

FIG. 8 is a graph showing relation between a ratio t/d and a gradient of current density;

FIGS. 9A and 9B are graphs showing the percent defective in terms of time;

FIG. 10 is a graph showing relation between the ratio t/d and the gradient of current density;

FIG. 11 is a plane view showing the layout of another multi-layered wiring structure according to the present invention; and

FIG. 12 is a plane view showing the layout of yet another multi-layered wiring structure according to the present invention.

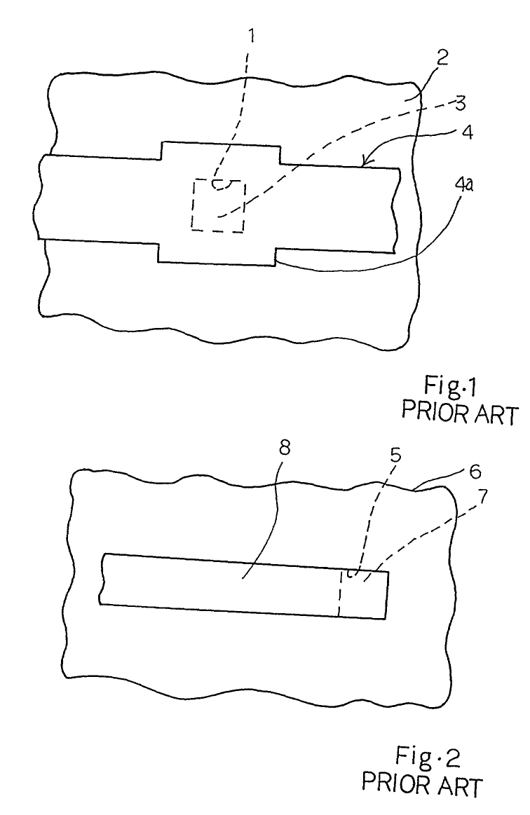

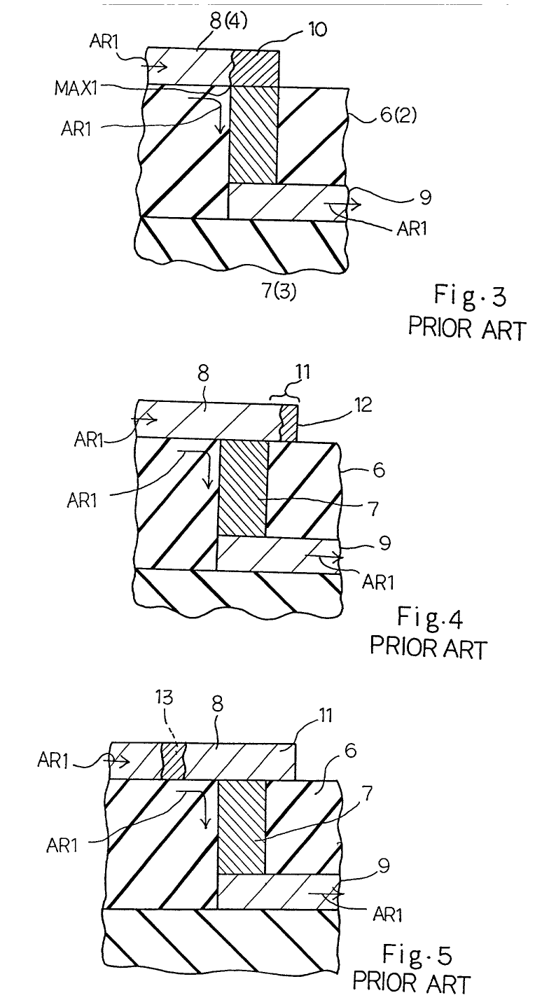

### DESCRIPTION OF THE PREFERRED EMBODIMENTS

First Embodiment

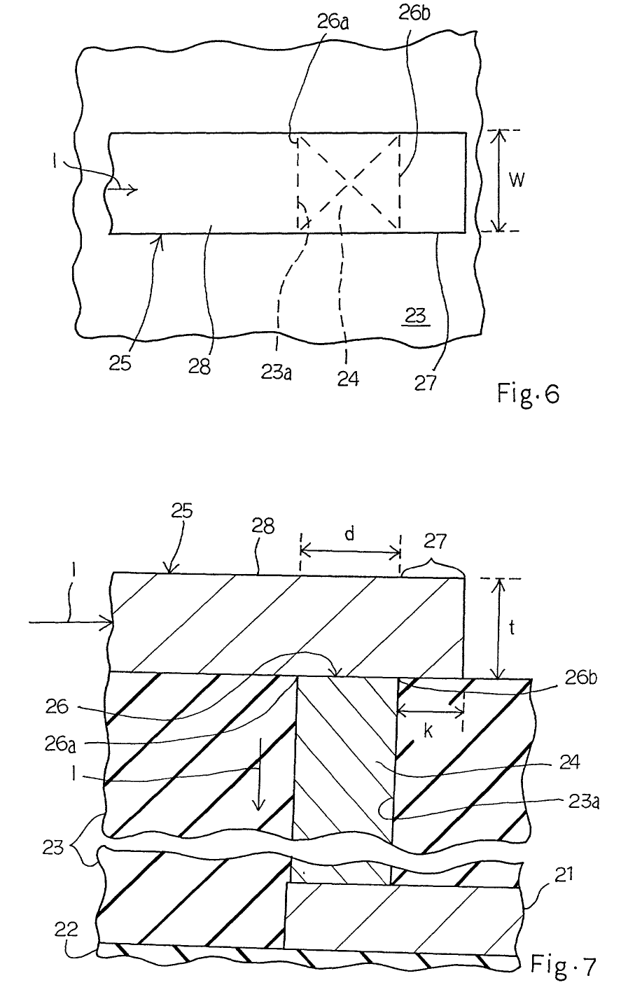

Referring to FIGS. 6 and 7, a multi-layered wiring structure has the borderless via structure, and comprises a lower conductive line 21 formed on a lower insulating layer 22, an inter-level insulating layer 23 covering the lower insulating layer 22, a conductive plug 24 filling a contact hole 23a formed in the inter-level insulating layer 23 and an upper conductive line 25 formed on the inter-level insulating layer 23. In this instance, the lower conductive line 21 and the upper conductive line 25 are formed of aluminum alloy such as, for example, aluminum alloy containing 1 wt. % silicon and 0.5 wt. % copper, and the conductive plug 24 is formed of tungsten. The conductive plug 24 is held in contact with the lower conductive line 21 and the upper conductive line 25, and is approximately equal in width to at least the upper conductive line 25 as shown.

A boundary 26 is formed between the upper surface of the conductive plug 24 and the lower surface of the upper conductive line 25, and electric current I flows from the upper conductive line 25 through the boundary 26 into the conductive plug 24. The upper conductive line 25 extends beyond the boundary 26, and the extension serves as a reservoir 27. The reservoir 27 is expected to supplement aluminum atoms to vacancy. Thus, the upper conductive line 25 partially provides a current path 28 to the electric current I, and partially serves as a reservoir 27. In the following description, term “upstream” is used for a position closer to a source of current than a “downstream” position.

The contact hole 23a has a square cross section, and, accordingly, the conductive plug 24 is shaped into a square pole. The contact hole 23a is indicated by “X” in FIG. 6 for clear discrimination. Even though the manufacturer designs the contact holes 23a to be square in cross section, the corners tend to be rounded through the optical pattern transfer from a photo mask to a photoresist layer, and the contact holes 23a have a circular cross section. When the square cross section measures less than 0.5 micron long, the tendency becomes clear. Such a deformation is unintentional, and is different from an elliptical cross section and a rectangular cross section described hereinlater in conjunction with the second and third embodiments.

The width of the upper conductive line 25 and, accordingly, the width of the conductive plug 24 are represented by “W”, and “d” is representative of the length of the boundary 26 or the length of the upper surface of the conductive plug 24 measured in the direction of the electric current I. If the contact hole 23a has a circular cross section or an elliptical cross section, the length “d” is corresponding to the diameter or the major axis in the direction of the current. The boundary 26 has two end lines 26a/26b, and the end line 26a is on the upstream side rather than the other end line 26b. The upper conductive line 25 has a thickness t, and the reservoir 28 projects from the end line 26b by length “k”.

The ratio of the thickness “t” to the length “d”, i.e., t/d is regulated to a certain value less than 1. The ratio t/d is preferably equal to or less than 0.75. The current density is maximized at the end line 26a, and the ratio t/d makes the gradient of current density different between a direction from the end line 26a toward the upstream side and a direction from the end line 26a toward the reservoir 27. When the ratio t/d is less than 1, the gradient of current density from the end line 26a toward the upstream side is smaller than the gradient of current density from the end line 26a toward the reservoir 27, and vacancy is diffused from part of the upper conductive line 25 around the end line 26a to the reservoir 27. In other words, the reservoir 27 effectively supplements the aluminum atoms to the vacancy. As a result, a void is hardly generated in the upper conductive line 25, and the reservoir 27 prolongs the lifetime of the upper conductive line 25.

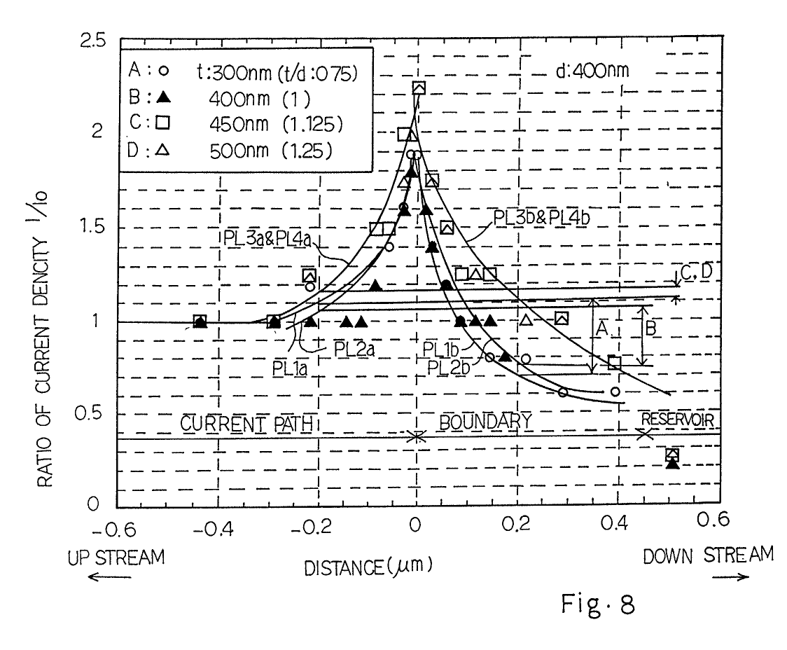

The present inventor carried out a simulation for the aluminum transport. The present inventor assumed the conductive material, the length “d”, the width “w” to be the aluminum alloy containing 1 wt. % silicon and 0.5 wt. % copper, 400 nanometers and 450 nanometers. The present inventor changed the thickness “t” from 300 nanometers through 400 nanometers and 450 nanometers to 500 nanometers. The current density was calculated, and was plotted in FIG. 8. In FIG. 8, the abscissa was indicative of the distance from the end line 26a, and the axis of coordinates was indicative of the ratio of actual current density to reference current density I/Io. The present inventor assumed the reference current density Io at a point sufficiently spaced from the end line 26a. When the thickness t was 300 nanometers, 400 nanometers, 450 nanometers and 500 nanometers, the ratio I/Io was indicated by white circles, black triangles, white squares and white triangles, and plots PL1a/PL1b, PL2a/PL2b, PL3a/PL3b and PL4a/PL4b were indicative of the gradient of current density. The plots PL1a/PL2a/PL3a/PL4a were representative of the gradient of current density toward the upstream side, and the plots PL1b/PL2b/PL3b/PL4b were representative of the gradient of current density toward the reservoir 27. Comparing the plots PL1a/PL2a/PL3a/PL4a with the plots PL1b/PL2b/PL3b/PL4b, the difference between the gradient of current density PL3a/PL4a at distance of −0.2 and the gradient of current density PL3b/PL4b at distance of 0.2 was “C” and “D”, and the ratio of current density PL1b/PL2b was greater than the ratio of current density PL1a/PL2a by Only 0.1. However, the difference between the gradient of current density PL1a/PL2a at distance of −0.2 and the gradient of current density PL1b/PL2b at distance of 0.2 was “A” and “B”, and the ratio of current density PL1b/PL2b was greater than the ratio of current density PL1a/PL2a by 0.4/0.3. Thus, the ratio t/d equal to or less than 1 made the gradient of current density PL1b/PL2b clearly larger than the gradient of current density PL1a/PL2a. The radio t/d equal to or less than 0.75 was more appropriate than the ratio t/d equal to 1.

Subsequently, the present inventor investigated the influence of the gradient of current density on the lifetime of the upper conductive line 25. First, the present inventor fabricated samples of the multi-layered wiring structure according to the present invention, i.e., ratio t/d≦1, and comparative samples with the ratio t/d greater than 1.

The samples according to the present invention were 450 nanometers in width w, 400 nanometers in length d and 300 nanometers in thickness t, and ten contact holes 23a were connected in series through the conductive lines and the tungsten pieces. The ratio t/d was 0.75. The samples according to the present invention had the reservoir 27, and the length k was 200 nanometers and 1000 nanometers.

The first comparative samples were also 450 nanometers in width w, 400 nanometers in length d and 300 nanometers in thickness t, and ten contact holes 23a were connected in series through the conductive lines and the tungsten pieces. The ratio t/d was also 0.75. The first comparative samples was designed not to have any reservoir, i.e., k=0. However, it was difficult to adjust the length k to zero, and the first comparative samples had an extremely small reservoir.

The second comparative samples were 450 nanometers in width w, 400 nanometers in length d and 500 nanometers in thickness t, and ten contact holes were also connected in series through the conductive lines and the tungsten pieces. The ratio t/d was 1.25, and the length k was zero, 200 nanometers and 1000 nanometers. It was also difficult to adjust the length k to zero, and a small reservoir was left in the conductive line.

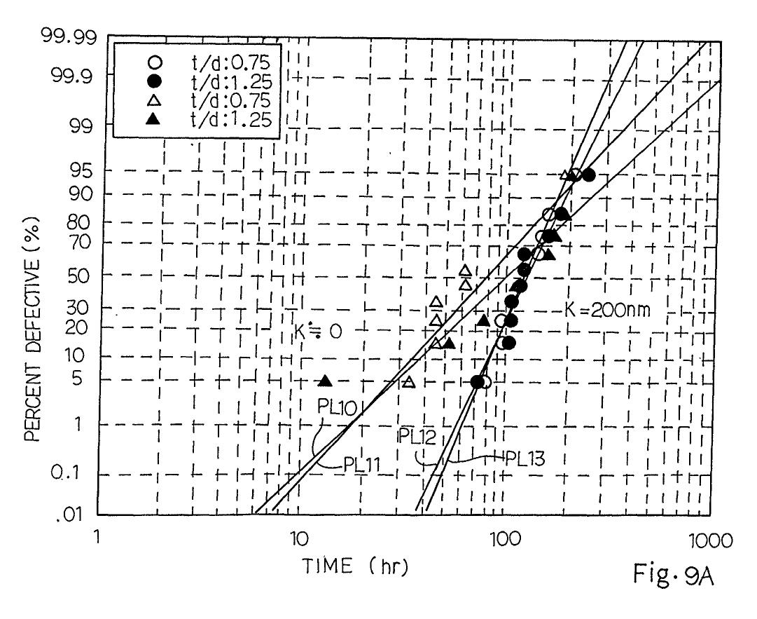

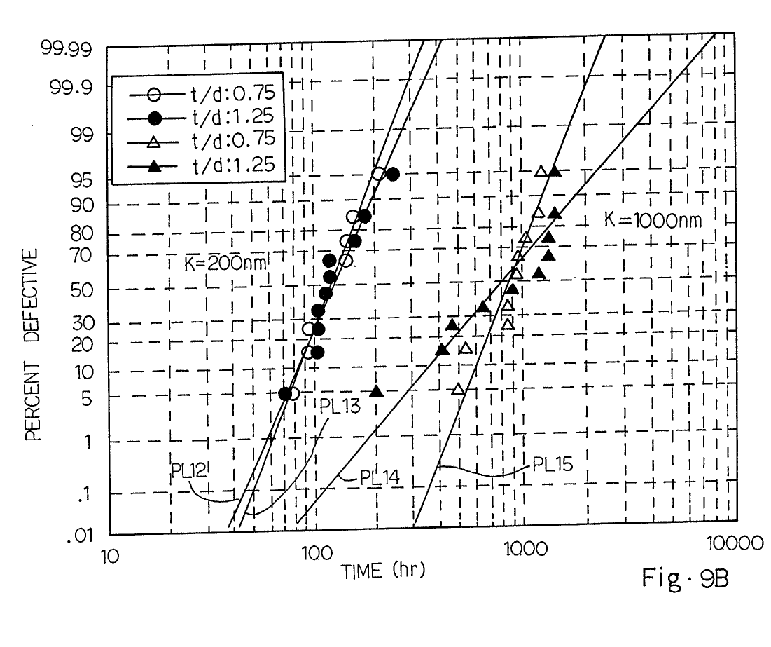

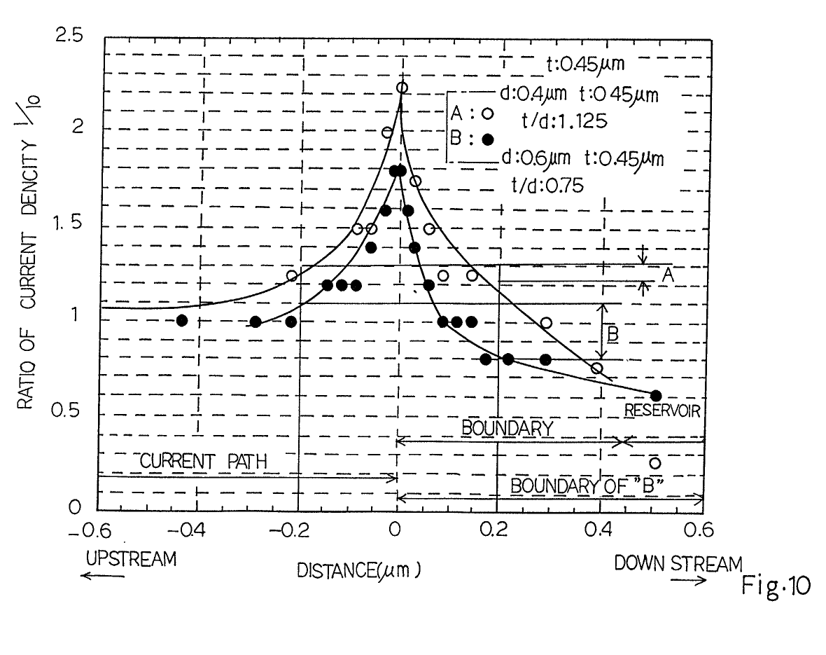

The present inventor maintained the temperature at 200 degrees in centigrade, and continuously flowed electric currents. The present inventor monitored the resistance against the electric current. When a sample increased the resistance at 10 percent, the present inventor assumed the sample to become defective, and the percent defective was plotted in FIGS. 9A and 9B.

In FIG. 9A, black triangles were indicative of the percent defective for the second comparative sample without a reservoir, i.e. k=0, and white triangles were indicative of the percent defective for the first comparative samples, i.e., k=0. The black triangles and the white triangles were approximated by lines PL10 and PL11, respectively. Black circles and white circles were indicative of the second comparative samples with the reservoir of 200 nanometers long and the samples with the reservoir of 200 nanometers long, and were approximated by lines PL12 and PL13, respectively. Although a small reservoir was left in the first and second comparative samples, the reservoir of 200 nanometers long surely prolonged the lifetime. The samples according to the present invention were on the line PL13. However, the second comparative samples were dispersed.

The advantages of the ratio t/d was clear from comparison between the samples with the reservoir of 1000 nanometer long and the second samples with the reservoir of 1000 nanometers long. In FIG. 9B, black triangles were indicative of the percent defective for the second samples with the reservoir of 1000 nanometers long, and white triangles were indicative of the percent defective for the samples with the reservoir of 1000 nanometers long. The percent defective of the second samples was approximated by line PL14, and the percent defective of the samples was approximated by line PL15. Although the reservoir of 1000 nanometers long was added to both samples, the samples according to the present invention had the lifetime longer than that of the second samples. Thus, the present inventor confirmed the influence of the ratio t/d.

The present inventor further carried out a simulation similar to that shown in FIG. 8. Although the length d was fixed and the thickness t was changed in the simulation shown in FIG. 8, the present inventor fixed the thickness t to 450 nanometers, and changed the length d. The samples according to the present invention had the length d of 600 nanometers, and the ratio t/d was 0.75. On the other hand, the comparative samples had the length d of 400 nanometers, and the ratio t/d was 1.125. Black circles were representative of the ratio of current density I/Io for the samples according to the present invention, and white circles were representative of the ratio of current density I/Io for the comparative samples. The comparative samples merely achieved difference A of current density between −0.2 micron and 0.2 micron, and the difference A was of the order of 0.1. On the other hand, the samples according to the present invention achieved large difference of the order of 0.3. Thus, the tendency was similar between the simulations.

As will be understood from the foregoing description, when the ratio t/d is equal to or greater than 1, the gradient of current density in the direction toward the reservoir 27 is large enough to supplement aluminum atoms to the vacancy in the boundary region, and the lifetime is prolonged.

Second Embodiment

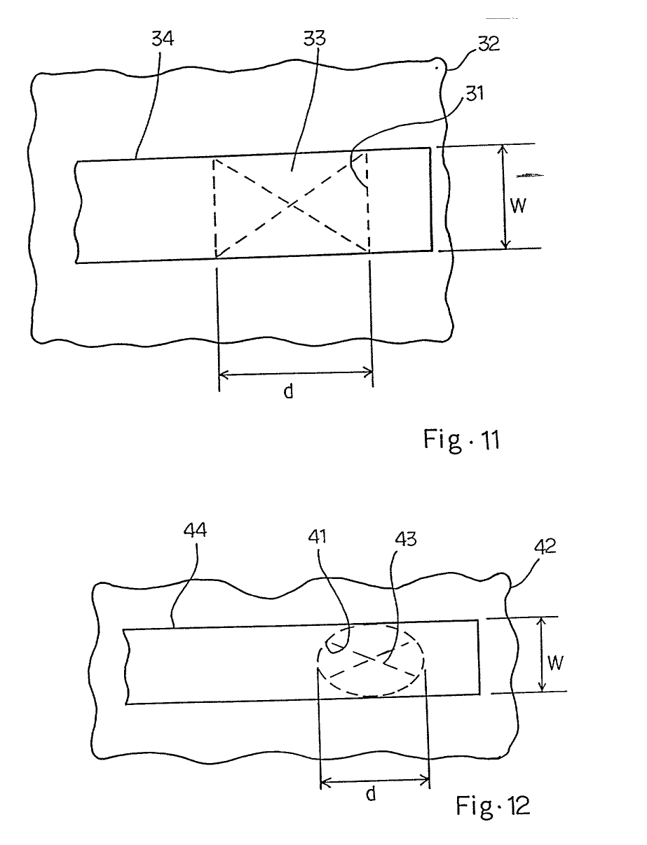

FIG. 11 illustrates another multi-layered wiring structure embodying the present invention. In this instance, a contact hole 31 is formed in an inter-level insulating layer 32, and is rectangular in cross section. The contact hole 31 is plugged with a tungsten piece 33, and an upper conductive line 34 is held in contact with the upper surface of the tungsten piece 33. The boundary between the tungsten piece 33 and the upper conductive line 34 is indicated by “X” in FIG. 11. The upper conductive line 34 is equal in width to the tungsten piece 33, and the multi-layered wiring structure has the borderless via structure. The boundary region has width “w” and length “d”, and the upper conductive line 34 has thickness “t”. The ratio t/d is equal to or less than 1, and is preferably equal to or less than 0.75.

The rectangular cross section increases the length d without increase the width w of the upper conductive line 34.

Third Embodiment

FIG. 12 illustrates yet another multi-layered wiring structure embodying the present invention. In this instance, a contact hole 41 is formed in an inter-level insulating layer 42, and has an elliptical cross section. The contact hole 41 is plugged with a tungsten piece 43, and an upper conductive line 44 is held in contact with the upper surface of the tungsten piece 43. The boundary between the tungsten piece 43 and the upper conductive line 44 is indicated by “X” in FIG. 12. The upper conductive line 44 is equal in width to the tungsten piece 43, and the multi-layered wiring structure has the borderless via structure. The boundary region is the elliptic, which has the minor axis “w” and the major axis “d”, and the upper conductive line 44 has thickness “t”. The ratio t/d is equal to or less than 1, and is preferably equal to or less than 0.75.

The elliptical cross section increases the length d without increase the width w of the upper conductive line 44.

Although particular embodiments of the present invention have been shown and described, it will be apparent to those skilled in the art that various changes and modifications may be made without departing from the spirit and scope of the present invention.

The upper conductive line may be formed of aluminum or another kind of conductive metal less resistive against the electromigration.

What is claimed is:

1. A multi-layered wiring structure incorporated in a semiconductor integrated circuit device, comprising:
an inter-level insulating layer having at least one contact hole open to an upper surface thereof and a lower surface thereof;
a conductive strip of a first conductive material formed on said inter-level insulating layer, extending over said contact hole, and providing a boundary region over said contact hole, a current path on an upstream side of said boundary region and a reservoir located on the opposite to said current path with respect to said boundary region and supplying metal atom to vacant generated in said conductive strip; and
a conductive plug formed of a second conductive material different from said first conductive material, filling said at least one contact hole and held in contact with said boundary region so that electric current flows from said current path through said boundary region into said conductive plug, the electric current density being maximized at a certain position in said boundary region, a gradient of said electric current density from said certain position toward said reservoir being larger than a gradient of said electric current density from said certain position toward said upstream side of said current path.

2. The multi-layered wiring structure as set forth in claim 1, in which a width of said boundary region is approximately equal to a first length of said conductive plug measured in a first direction perpendicular to a second direction in which said electric current flows along said current path.

3. The multi-layered wiring structure as set forth in claim 2, in which said conductive plug and said conductive strip respectively have a second length measured in said second direction and a thickness, respectively, and the ratio of said thickness to said second length is equal to or less than 1.

4. The multi-layered wiring structure as set forth in claim 3, in which said at least one contact hole has a rectangular cross section.

5. The multi-layered wiring structure as set forth in claim 3, in which said at least one contact hole has an elliptical cross section.

6. The multi-layered wiring structure as set forth in claim 4, in which said reservoir projects from said boundary region by at least 200 nanometers.

7. The multi-layered wiring structure as set forth in claim 2, in which said conductive plug and said conductive strip respectively have a second length measured in said second direction and a thickness, respectively, and the ratio of said thickness to said second length is equal to or less than 0.75.

8. The multi-layered wiring structure as set forth in claim 7, in which said at least one contact hole has a rectangular cross section.

9. The multi-layered wiring structure as set forth in claim 7, in which said at least one contact hole has an elliptical cross section.

10. The multi-layered wiring structure as set forth in claim 8, in which said reservoir projects from said boundary region by at least 200 nanometers.

11. The multi-layered wiring structure as set forth in claim 1, in which said first conductive material and said second conductive material are one of aluminum and aluminum alloy and tungsten, respectively.

12. The multi-layered wiring structure as set forth in claim 11, in which said aluminum alloy contains silicon and copper.

13. The multi-layered wiring structure as set forth in claim 12, in which said silicon is of the order of 1 percent by weight, and said copper is of the order of 0.5 percent by weight.
